(19) United States
(12) Patent Application Publication
(10) Pub. No.: US 2026/0177587 A1
(43) Pub. Date: Jun. 25, 2026

(54) PROBE CONNECTION DEVICE, BRACKET ASSEMBLY THEREOF, AND REVERSE BIAS PROCESSING DEVICE COMPRISING SAME

(71) Applicant: HANWHA SOLUTIONS CORPORATION, Seoul (KR)

(72) Inventor: Sang Min YEON, Seoul (KR)

(21) Appl. No.: 19/127,836

(22) PCT Filed: Mar. 14, 2024
(86) PCT No.: PCT/KR2024/095545

§ 371 Date: May 7, 2025

(30) Foreign Application Priority Data
Mar. 15, 2023 (KR) 10-2023-0034019

(51) Int. Cl. G01R 3/00; G01R 1/067; G01R 1/073; H10F 77/20

(52) U.S. Cl. CPC G01R 3/00; G01R 1/06716; G01R 1/07342; G01R 1/07378; H10F 77/211

(57) ABSTRACT

Provided are a probe connection device capable of improving the lifespan of a probe, a bracket assembly thereof, and a reverse-bias processing device including the same. According to the present disclosure, the probe connection device includes: a circuit board fixed to a first bracket; a probe including a body portion configured to be in close contact with the circuit board and a leg portion connected to the body portion and having an end configured to contact an object; and a second bracket configured to press one side of the body portion toward the circuit board while remaining spaced apart from the leg portion.

### TECHNICAL FIELD

The present disclosure relates to a probe connection device, a bracket assembly thereof, and a reverse-bias processing device including the same, and more particularly, to a probe connection device capable of improving the lifespan of a probe, a bracket assembly thereof, and a reverse-bias processing device including the same.

### BACKGROUND ART

The laser-enhanced contact optimization (LECO) technique is a technology that improves the contact resistance between electrodes and the light-receiving surface of silicon-based solar cells by using a laser and reverse bias. When pinholes form in individual solar cells within a solar cell module, the power generation characteristics deteriorate. To improve the power generation characteristics, a process can be performed in which a reverse-bias voltage is applied between the electrodes of adjacent solar cells to eliminate the pinholes.

When a laser and a reverse-bias voltage are applied, current concentrates in the pinhole regions, generating localized heat. As a result, the metal in the affected area either scatters or oxidizes, transforming into an insulating film. This process electrically isolates and eliminates the pinhole, thereby preventing degradation of power generation characteristics.

A reverse-bias processing device for a solar module according to the relevant art is shown in FIG. 1. Referring to FIG. 1, the conventional configuration improves contact resistance between the electrode and the light-receiving surface by applying a reverse voltage to the upper probe (+pole) 7 and the lower substrate (−pole) 3, while irradiating the solar cell with a laser from a laser irradiation unit 1.

In the relevant art, when fixing the probe 7 and a circuit board 2 to a bracket 5 (5a, 6b) (two-layered, left/right) via a fixing unit 6 to connect to an upper surface 4a of a solar cell 4, a leg portion 7b—which is elastically supported relative to a body portion 7 a of the probe 7—experiences friction-induced damage during vertical movement caused by the left/right compression of the bracket 5. Consequently, the probe 7 fails to meet the guaranteed usage cycle specified by its manufacturer (e.g., one million cycles), leading to damage and failure of the leg portion 7b.

### DISCLOSURE

### Technical Problem

To address the aforementioned problems, the present disclosure provides a probe connection device, a bracket assembly thereof, and a reverse-bias processing device including the same, configured to extend the service life of a probe beyond its manufacturer-guaranteed usage cycle by modifying the shape of the bracket that connects and secures the probe to a circuit board.

The objectives described above are not exhaustive, and additional advantages and features of the present disclosure will become apparent to those skilled in the art from the following detailed description.

### Technical Solution

According to one aspect of the present disclosure, a probe connection device includes: a circuit board fixed to a first bracket; a probe including a body portion configured to be in close contact with the circuit board and a leg portion connected to the body portion, the leg portion having an end configured to contact an object; and a second bracket configured to press one side of the body portion toward the circuit board while remaining spaced apart from the leg portion.

The probe connection device may further include a fixing unit that extends through the first bracket and the second bracket to couple the first and second brackets together.

The fixing unit may be coupled to and extending through the circuit board between the first bracket and the second bracket.

A separation groove portion may be formed on a first surface of the second bracket, which faces the circuit board, to prevent the second bracket from contacting the leg portion.

The separation groove portion may be formed as a separation groove on the first surface and extending parallel to the leg portion.

The body portion may be formed such that a portion of the body portion contacts the first surface, and the remaining portion of the body portion is located within the separation groove portion.

An inner end portion of the separation groove portion, which is formed on the first surface of the second bracket, may be positioned to contact the body portion.

An inner surface of the separation groove portion of the second bracket may include a surface parallel to the first surface.

An inner surface of the separation groove portion of the second bracket may include a surface inclined relative to the first surface.

The body portion of the probe may be shorter than the leg portion.

According to another aspect of the present disclosure, a bracket assembly includes: a first bracket to which a circuit board is fixed; and a second bracket arranged to face the first bracket and configured to press a probe connected to the circuit board toward the circuit board, wherein a separation groove portion may be formed on a first surface of the second bracket, which faces the circuit board, to prevent the second bracket from contacting one side of the probe.

The probe may include a body portion and a leg portion connected to the body portion, the leg portion having an end configured to contact an object, wherein the one side of the probe may be the leg portion.

The bracket assembly may further include a fixing unit extending through the first bracket and the second bracket to couple the first and second brackets together.

The fixing unit may pass through the circuit board, between the first bracket and the second bracket, to couple the first bracket and the second bracket together.

The separation groove portion may be formed on the first surface as a separation groove extending parallel to the leg portion.

The body portion may be formed such that a portion of the body portion contacts the first surface, and the remaining portion of the body portion is positioned within the separation groove portion.

An inner surface of the separation groove portion of the second bracket may include a surface parallel to the first surface.

An inner surface of the separation groove portion of the second bracket may include a surface inclined relative to the first surface.

According to another aspect of the present disclosure, a reverse-bias processing device includes: a laser irradiation unit configured to irradiate a laser onto one surface of an object; a probe connection device configured to maintain continuous electrical connection with the object via a probe and configured to allow a leg portion of the probe to move without friction during operation of the probe; a power supply unit having one end electrically connected to a substrate supporting the object and the other end electrically connected to the probe connection device.

The probe connection device may include: a circuit board fixed to a first bracket; a probe including a body portion configured to be in close contact with the circuit board and a leg portion connected to the body portion, the leg portion having an end configured to contact an object; and a second bracket configured to press one side of the body portion toward the circuit board while remaining spaced apart from the leg portion.

The reverse-bias processing device may further include a fixing unit that is coupled through the first bracket and the second bracket.

The fixing unit may be coupled to and extending through the circuit board between the first bracket and the second bracket.

A first surface of the second bracket, which faces the circuit board, may have a separation groove portion formed therein to prevent the second bracket from contacting the leg portion.

One surface of the object may be a front surface or a rear surface, and the substrate may be disposed on the rear surface to support the object.

The laser irradiation unit may be disposed adjacent to the rear surface of the object, and the substrate may be provided with a laser irradiation hole through which the laser may be irradiated.

The object may be a solar cell or a solar module.

The probe connection device may be used to improve the contact resistance between an electrode and a light-receiving surface of a solar cell serving as the object, by utilizing a laser and reverse bias.

### Advantageous Effects

With the above configuration, a probe connection device, a bracket assembly thereof, and a reverse-bias processing device including the same, according to an embodiment of the present disclosure, allow the operating part of a probe fixed to a circuit board to remain spaced apart from the bracket securing the probe during operation. This configuration can prevent friction-induced damage and enable use of the probe beyond its guaranteed usage cycle.

### DESCRIPTION OF DRAWINGS

FIG. 1 is a front view of a reverse-bias processing device for a solar module in the relevant art.

FIG. 2 is a front view of a reverse-bias processing device incorporating a probe connection device and a bracket assembly thereof according to an embodiment of the present disclosure are applied.

FIG. 3 is an exploded perspective view of a probe connection device and a bracket assembly thereof according to an embodiment of the present disclosure.

FIG. 4 is an operation diagram of a probe, which is a component of a probe connection device and a bracket assembly thereof according to an embodiment of the present disclosure.

FIGS. 5 and 6 are perspective views of a second bracket, which is a component of a probe connection device and a bracket assembly thereof according to another embodiment of the present disclosure.

FIG. 7 is a front view of a reverse-bias processing device according to another embodiment of the present disclosure.

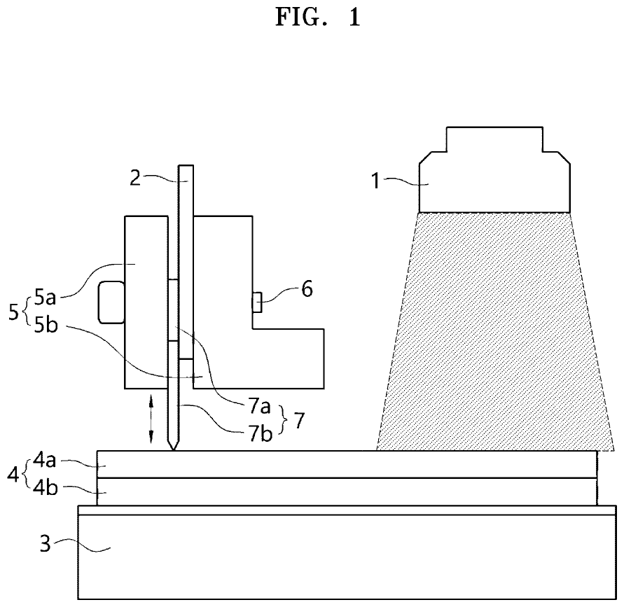

### BEST MODE

Hereinafter, various embodiments of the present disclosure will be described in detail with reference to the accompanying drawings so that those skilled in the art to which the present disclosure pertains can easily carry out the invention. The present disclosure may be embodied in many different forms and should not be construed as limited to the embodiments set forth herein. In order to clearly describe the present disclosure, components that are not directly relevant to the description are omitted in the drawings, and like or similar elements are denoted by like reference numerals throughout the specification.

The words and terms used in the present specification and claims should not be construed as limited to their ordinary or dictionary meanings, but should be interpreted in a manner consistent with the technical scope of the present disclosure, in accordance with the principle that an inventor may define terms and concepts to best describe the invention.

Therefore, the embodiments described in the present specification and the configurations shown in the drawings are merely preferred examples of the present disclosure and do not represent the entirety of the technical ideas of the present disclosure. Accordingly, it should be understood that various equivalent modifications and substitutions may exist at the time of filing of the present disclosure.

In the present specification, terms such as “comprise” or “have” are intended to describe the presence of a stated feature, integers, step, operation, element, component, or a combination thereof, but should not be understood as precluding the presence or addition of one or more other features, integers, steps, operations, elements, components, or combinations thereof.

Unless specifically stated otherwise, when an element is referred to as being “in front of”, “behind”, “above”, or “below” another element, this includes cases where the element is directly in contact with the other element as well as cases where one or more other elements are interposed therebetween. Also, unless specifically stated otherwise, when an element is referred to as being “connected” to another element, this includes both direct and indirect connections through one or more intermediate elements.

Hereinafter, a probe connection device and a bracket assembly thereof, according to an embodiment of the present disclosure, will be described with reference to the drawings.

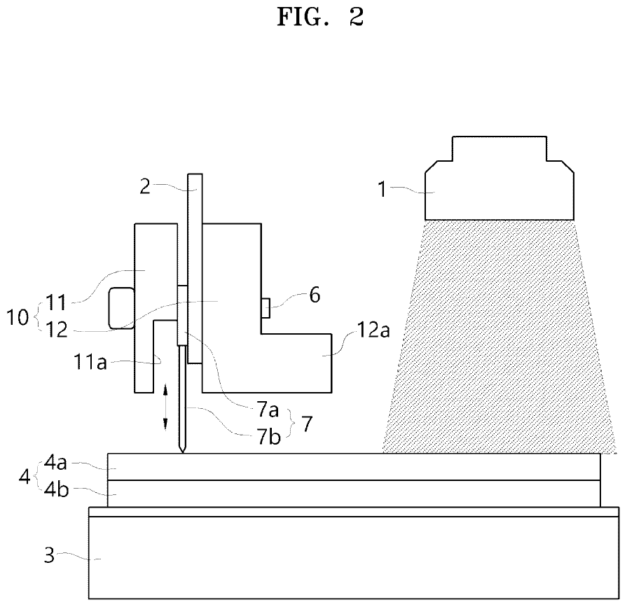

Referring to FIGS. 2 to 4, a probe connection device according to an embodiment of the present disclosure may include a circuit board 2, a probe 7, a fixing bracket 10, and a fixing unit 6.

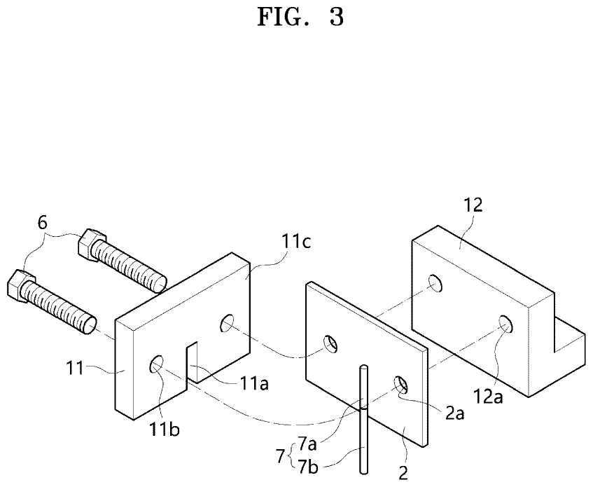

Referring to FIGS. 2 and 3, the circuit board 2 may be fixed in close contact with a first bracket 12. At this time, the fixing bracket 10 may include the first bracket 12 and a second bracket 11. Accordingly, the circuit board 2 may be fixed between the first bracket 12 and the second bracket 11, as the first bracket 12 and the second bracket 11 are fastened together by the fixing unit 6.

Although not shown in the drawings, the circuit board 2 may be electrically connected to a power supply unit generating power via a power cable and may receive power from the power supply unit.

Referring to FIGS. 2 to 4, the probe 7 may include a body portion 7a, which is configured to be in close contact with the circuit board 2, and a leg portion 7b, which is connected to the body portion 7a, wherein an end of the leg portion 7b is configured to contact an object, such as a solar cell 4.

At this time, the body portion 7a may have therein an elastic member (not shown), such as a spring, and the leg portion 7b may operate while being elastically supported along its longitudinal direction by the elastic force of the elastic member.

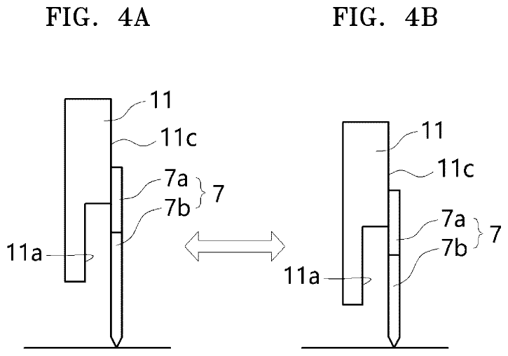

Referring to FIGS. 2 and 4, the second bracket 11 may be configured to press one side of the body portion 7a (left side based on FIG. 2) toward the circuit board 2, while remaining spaced apart from the leg portion 7b.

As such, because the leg portion 7b remains spaced apart from the second bracket 11, no friction occurs between the leg portion 7b and the second bracket 11 during operation of the leg portion 7b, thereby ensuring smooth operation and extending the service life of the probe 7.

That is, while the leg portion 7b, which is capable of moving relative to the body portion 7a, maintains contact with the solar cell 4, when the body portion 7a, the circuit board 2, and the fixing bracket 10 move vertically (the up-and-down direction in FIG. 2), friction is prevented due to the separation between the leg portion 7 b and the fixing bracket 10—specifically the second bracket 11—thereby preventing damage to the leg portion 7b.

In an alternative embodiment, the width of the leg portion 7b may be formed to be relatively smaller than that of the body portion 7a. In addition, the diameter of the leg portion 7b may be formed to be relatively smaller than that of the body portion 7a.

Accordingly, as the distance between the second bracket 11 and the circuit board 2 is determined by the width (or diameter) of the body portion 7a, the leg portion 7b may remain spaced apart from both the second bracket 11 and the circuit board 2.

Furthermore, because the leg portion 7b remains spaced apart from the second bracket 11 and the circuit board 2, no friction occurs between the leg portion 7b and the second bracket 11 or the circuit board 2, even when the body portion 7a, the fixing bracket 10, and the circuit board 2 move together. As a result, wear on the leg portion 7b may be prevented.

Referring to FIGS. 2 and 3, the fixing unit 6 may be coupled through the first bracket 12 and the second bracket 11. At this time, a plurality of fixing units 6 may be provided.

At this time, the fixing unit 6 may be coupled to and extending through the circuit board 2, between the first bracket 12 and the second bracket 11. Accordingly, the circuit board 2 may be formed with a fastening hole 2a, through which the fixing unit 6 may be fastened.

At this time, on a first surface 11c of the second bracket 11, which faces the circuit board 2, a separation groove portion 11a may be formed to prevent the second bracket 11 from coming in contact with the leg portion 7b.

At this time, the separation groove portion 11a may be formed on the first surface 11c as a separation groove extending parallel to the leg portion 7b. Accordingly, the leg portion 7b may remain free of contact with the separation groove portion 11a at all positions.

At this time, the body portion 7a may be formed such that a part of the body portion 7a is in contact with the first surface 11c, while the remaining part of the body portion 7a is positioned within the separation groove portion 11a. With the body portion 7a configured in this manner, the leg portion 7b may remain spaced apart from the separation groove portion 11a.

At this time, an inner end portion of the separation groove portion 11a, which is formed on the first surface 11c of the second bracket 11, may be positioned in contact with the body portion 7a.

In cases where the separation groove portion 11a is formed as a step through grinding of the first surface 11c, the body portion 7a may be positioned on that step, thereby fundamentally preventing the leg portion 7b from coming into contact with and generating friction against the first surface 11c of the second bracket 11.

In an alternative embodiment, the first surface 11c may be formed with a seating groove portion (not shown), which has a shape corresponding to the outer peripheral shape of the body portion 7a.

With the body portion 7a seated in the seating groove portion, the position of the probe 7 may be stably fixed.

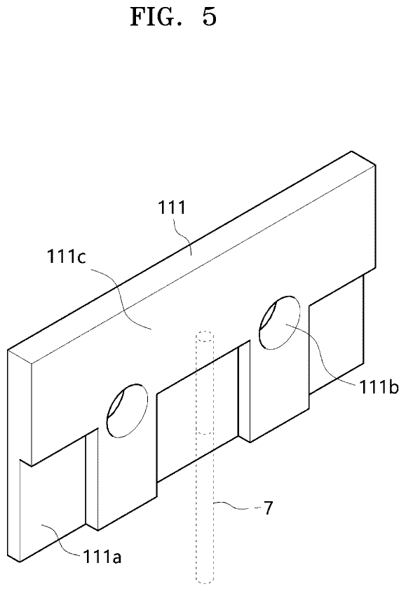

Referring to FIG. 5, the inner surface of the separation groove portion 111a of the second bracket 111 may include a surface parallel to the first surface 111c. In other words, when the separation groove portion 111a is formed by grinding the first surface 111c of the second bracket 111, the grinding may be performed so that the separation groove portion 111 remains parallel to the first surface 111c.

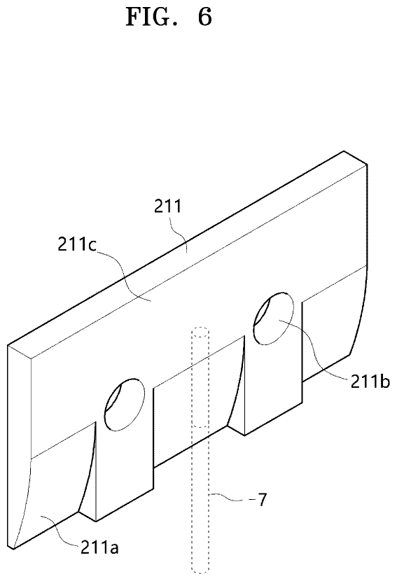

Referring to FIG. 6, the inner surface of the separation groove portion 211a of the second bracket 211 may include a surface inclined relative to the first surface 211c. Forming the separation groove portion 211a as an inclined surface on the first surface 211c may be advantageous in terms of grinding processing.

Meanwhile, the probe 7 may be configured such that the body portion 7a has a shorter length than the leg portion 7b. This design may prevent the body portion 7a from coming into contact with the object or experiencing impact due to insufficient stroke.

In an alternative embodiment, with reference to the height direction of probe 7 (the up-and-down direction in FIG. 2), the lower end (based on FIG. 2) of the body portion 7a may be positioned lower than the lower end of the circuit board 2.

This configuration allows the leg portion 7b capable of moving relative to the body portion 7a to remain spaced apart from the circuit board 2, and since no friction occurs between the leg portion 7b and the circuit board 2 even when the body portion 7a, the fixing bracket 10, and the circuit board 2 move together, wear on the leg portion 7b may be prevented.

FIG. 2 shows a front view of a reverse-bias processing device for a solar module, incorporating a probe connection device and a bracket assembly thereof according to an embodiment of the present disclosure are applied.

A solar cell 4 may be installed on top of a lower substrate 3 such that the solar cell 4 is supported from below. The lower substrate 3 has a negative potential, and accordingly, a lower surface 4b of the solar cell 4 has a positive potential, while an upper surface 4a of the solar cell 4 has a negative potential.

A probe 7 may be positioned vertically above the solar cell 4. The lower end of the leg portion 7b of the probe 7 may remain in continuous contact with the upper surface 4a of the solar cell 4.

Accordingly, the current supplied to the circuit board 2, which has a positive potential, may continuously flow to the solar cell 4.

Functionally, the body portion 7a of the probe 7 may be configured to operate relative to the leg portion 7b and may be press-fitted and secured between the second bracket 11 and the circuit board 2.

The probe 7 and the circuit board 2 may be positioned between the first bracket 12 and the second brackets 11, which form the fixing bracket 10, and the first bracket 12 and the second brackets 11 are fastened and secured by the fixing unit 6. As a result, the first bracket 12, the probe 7, the circuit board 2, and the second bracket 11 are fixed in a compressed state, and they may perform a reciprocating lifting operation together based on the support provided by the leg portion 7b.

A laser irradiation unit 1 may be provided above the solar cell 4 and configured to irradiate the solar cell with a laser beam in conjunction with reverse-bias processing, to improve the power generation characteristics of the solar cell.

Since the friction issue between the leg portion 7b of the probe 7 and the second bracket 11 during operation of the probe 7 has been resolved, the probe may remain fully operational for up to three million cycles, even if, for example, its guaranteed service life is only one million cycles.

FIG. 3 shows an exploded perspective view of a probe connection device and a bracket assembly thereof according to an embodiment of the present disclosure. The second bracket 11 may include a plurality of fastening holes 11b through which the fixing unit 6 extends, and the fixing unit 6 may be configured to pass through each of the fastening holes 11b.

In addition, a separation groove portion 11a may be formed on one side of the second bracket 11, and the portion corresponding to the separation groove portion 11a may be the leg portion 7b of the probe 7. At this time, to ensure proper spacing of the leg portion 7b, a portion of the body portion 7a may be positioned to align with the separation groove portion 11a.

The circuit board 2 may be configured to be press-fitted and secured with the probe 7 and may include a fastening hole 2a for coupling with the fixing bracket 10. The first bracket 12 may also include a fastening hole 12b, and the fixing unit 6 may be screw-fastened into the fastening hole 12b.

FIG. 4 shows an operation diagram of a probe, which is a component of a probe connection device and a bracket assembly thereof, according to an embodiment of the present disclosure. In FIG. 4A shows a state in which the second bracket 11 has moved upward to a raised position, while FIG. 4B shows a state in which the second bracket 11 has moved downward.

The probe 7 and the circuit board 2 are fixed by the first and second brackets 12 and 11, and in this state, the body portion 7a of the probe 7, the circuit board 2, and the fixing bracket 10 may move reciprocally. During this movement, the leg portion 7b may remain in contact with the solar cell 4 due to the elastic force of a spring embedded in the body portion 7a.

FIG. 5 shows a perspective view of a second bracket, which is a component of a probe connection device and a bracket assembly thereof, according to another embodiment of the present disclosure.

In particular, the second bracket 111 of the fixing bracket may include a fastening hole 111b formed therein, and a separation groove portion 111a may be formed as a step on the surface of the second bracket 111 that is in close contact with the probe 7, wherein the separation groove portion 111a is formed parallel to the first surface 111c, thereby allowing the leg portion 7b to remain spaced apart from the second bracket 111.

That is, by forming a step in the portion of the second bracket 111 where the probe 7 is positioned, the leg portion 7b may remain spaced apart from the second bracket 111.

Although the grinding area increases due to the formation of a step, such a step may be more advantageous in terms of manufacturing compared to the previous embodiment, in which the separation groove portion 11a is formed in alignment with the positions when a large number of probes 7 are arranged.

In this case, the separation groove portion 111a is not formed around the area on the first surface 111c where the fastening hole 111b is located.

That is, when multiple separation groove portions 111a are to be formed, the fastening holes 111b may be arranged between the separation groove portions 111a, and the separation groove portions 111a and the fastening holes 111b may be offset from each other rather than being aligned along the same axis in the height direction (the up-and-down direction based on FIG. 5).

FIG. 6 shows a perspective view of a second bracket, which is a component of a probe connection device and a bracket assembly thereof, according to another embodiment of the present disclosure.

The separation groove portion 211a, which is formed on the first surface 211c in the previously described embodiments, may be formed as an inclined surface. Since the leg portion 7b of the probe 7 is positioned within the inclined surface, which corresponds to the separation groove portion 211a, the leg portion 7b may remain free from friction. In this configuration, the fastening holes 211b may be formed in the second bracket 211 in the same manner as in the previously described embodiments. In addition, the separation groove portion 211a may be formed as either an inclined surface or a rounded surface.

The separation groove portion 211a may be formed as a convex curved surface toward the probe 7. Furthermore, in the direction from the body portion 7a toward the leg portion 7b (from the upper side to the lower side in FIG. 6), the distance between the separation groove portion 211a and the leg portion 7b may gradually increase.

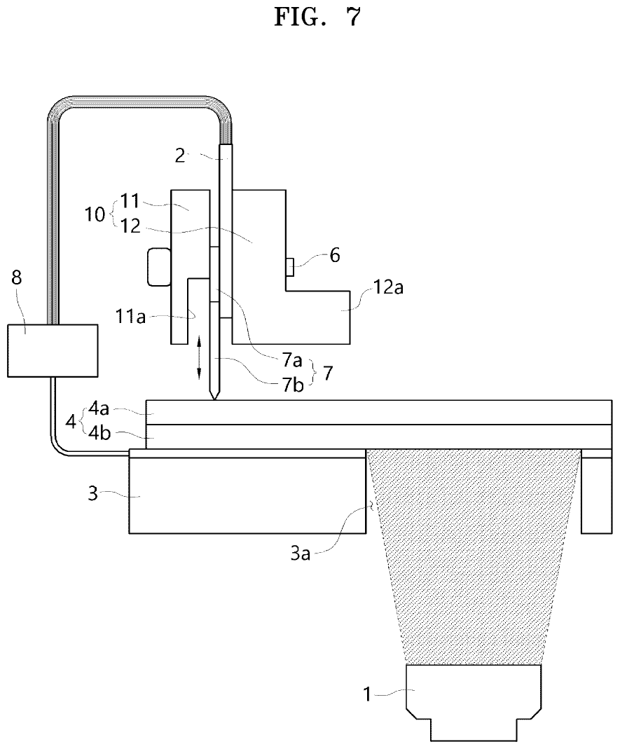

FIG. 7 shows a front view of a reverse-bias processing device according to another embodiment of the present disclosure. According to an embodiment of the present disclosure, the reverse-bias processing device may include a laser irradiation unit 1, a probe connection device, and a power supply unit 8, as described above.

The laser irradiation unit 1 may be configured to irradiate a laser onto one side of an object. Referring to FIG. 7, the laser irradiation may be performed from below the substrate 3.

At this time, the one side of the object may be either the front or the rear surface, and the substrate 3 may be disposed beneath the rear surface to support the object.

At this time, the object may be a solar cell or a solar module.

In FIG. 7, the object may be a solar module, where the front surface corresponds to the upper surface 4a of the solar module 4, and the rear surface corresponds to the lower surface 4b of the solar module 4.

In this configuration, the laser irradiation unit 1 may be disposed adjacent to the rear surface of the solar module 4, and the substrate 3 may be provided with a laser irradiation hole 3a to allow the laser to pass through. Accordingly, the laser may pass through the laser irradiation hole 3a and be directed onto the rear surface, e.g., the lower surface 4b, of the solar module 4.

Referring to FIG. 7, the probe connection device may be configured to maintain continuous electrical connection with the object, e.g., the solar module 4, via the probe 7, and may be configured such that during the operation of the probe 7, the leg portion 7b of the probe 7 operates without friction against the fixing bracket 10 and the circuit board 2.

Here, the probe connection device may be configured similarly to the previously described embodiments.

That is, the probe connection device may include: a circuit board 2 fixed to a first bracket 12; a probe 7 including a body portion 7a configured to be in close contact with the circuit board 2 and a leg portion 7b connected to the body portion 7a, the leg portion 7b having an end configured to contact an object; a second bracket 11 configured to press one side of the body portion 7a against the circuit board 2 while remaining spaced apart from the leg portion 7b; and a fixing unit 6 coupled through the first bracket 12 and the second bracket 11.

The circuit board 2 may be electrically connected to a power supply unit 8, which generates power, through a power cable (reference numeral not assigned) and may receive power from the power supply unit 8.

Referring to FIG. 7, the power supply unit 8 may have one end electrically connected to the substrate 3, which supports the solar module 4, and the other end electrically connected to the circuit board 2 of the probe connection device.

According to an embodiment of the present disclosure, the power generated by the power supply unit 8 may be direct current (DC). However, within the technical scope that enables reverse-bias processing, various modifications may be possible, such as configuring the power supply unit 8 to generate alternating current (AC). In addition, the reverse-bias processing device according to the present disclosure may be used to improve the contact resistance between the electrode and the light-receiving surface of the object by utilizing both laser irradiation and reverse bias.

That is, applying a laser and a reverse-bias voltage causes current to concentrate at pinhole regions formed on the target object 4, localized heat. As a result, the metal in the affected area either scatters or oxidizes, transforming into an insulating film. This process electrically isolates and eliminates the pinhole, thereby preventing degradation of power generation characteristics.

Although embodiments of the present disclosure have been described, the spirit of the present disclosure is not limited by the embodiments presented herein, and those skilled in the art who understand the spirit of the present disclosure can readily propose other embodiments within the conceptual scope by adding, modifying, deleting, or supplementing components. Such variations also fall within the scope of the present disclosure.

### INDUSTRIAL APPLICABILITY

According to the present disclosure, provided are a probe connection device, a bracket assembly thereof, and a reverse-bias processing device including the same. Furthermore, embodiments of the present disclosure may be applied to mechanisms and devices used for reverse-bias processing in industrial applications.

1. A probe connection device comprising:
a circuit board fixed to a first bracket;
a probe comprising a body portion configured to be in close contact with the circuit board, and a leg portion connected to the body portion, the leg portion having an end configured to contact an object; and
a second bracket configured to press one side of the body portion toward the circuit board while remaining spaced apart from the leg portion.

2. The probe connection device of claim 1, further comprising a fixing unit extending through and coupled to the first bracket and the second bracket.

3. The probe connection device of claim 1, wherein a first surface of the second bracket, which faces the circuit board, comprises a separation groove portion arranged to prevent the second bracket from contacting the leg portion.

4. The probe connection device of claim 3, wherein the separation groove portion is formed on the first surface as a separation groove extending parallel to the leg portion.

5. The probe connection device of claim 3, wherein the body portion is formed such that a part of the body portion is in contact with the first surface while a remaining part of the body portion is positioned within the separation groove portion.

6. The probe connection device of claim 3, wherein an inner end portion of the separation groove portion formed on the first surface of the second bracket is positioned to contact the body portion.

7. The probe connection device of claim 3, wherein an inner surface of the separation groove portion of the second bracket comprises a surface parallel to the first surface.

8. The probe connection device of claim 3, wherein an inner surface of the separation groove portion of the second bracket comprises a surface inclined relative to the first surface.

9. A bracket assembly comprising:
a first bracket to which a circuit board is fixed; and
a second bracket arranged to face the first bracket and configured to press a probe connected to the circuit board toward the circuit board,
wherein a first surface of the second bracket, which faces the circuit board, comprises a separation groove portion configured to prevent one side of the probe from contacting with the second bracket.

10. The bracket assembly of claim 9, wherein the probe comprises:
a body portion; and
a leg portion connected to the body portion and comprising an end configured to contact an object,
wherein the one side of the probe is the leg portion.

11. The bracket assembly of claim 10, further comprising a fixing unit extending through and coupled to the first bracket and the second bracket.

12. The bracket assembly of claim 11, wherein the fixing unit extends through the circuit board, between the first bracket and the second bracket, to couple the first bracket and the second bracket together.

13. A reverse-bias processing device comprising:
a laser irradiation unit configured to irradiate a laser onto one surface of an object;
a probe connection device configured to maintain continuous electrical connection with the object via a probe and configured to allow a leg portion of the probe to move without friction during operation of the probe;
a power supply unit having one end electrically connected to a substrate supporting the object and the other end electrically connected to the probe connection device.

14. The reverse-bias processing device of claim 13, wherein the probe connection device comprises:
a circuit board fixed to a first bracket;
a probe comprising a body portion configured to be in close contact with the circuit board and a leg portion connected to the body portion, the leg portion having an end configured to contact an object; and
a second bracket configured to press one side of the body portion toward the circuit board while remaining spaced apart from the leg portion.

15. The reverse-bias processing device of claim 14, further comprising a fixing unit extending through and coupled to the first bracket and the second bracket.

16. The reverse-bias processing device of claim 14, wherein a first surface of the second bracket, which faces the circuit board, comprises a separation groove portion formed thereon to prevent the second bracket from contacting the leg portion.

17. The reverse-bias processing device of claim 13, wherein the one surface of the object is a front surface or a rear surface, and the substrate is disposed on the rear surface to support the object.

18. The reverse-bias processing device of claim 17, wherein the laser irradiation unit is disposed adjacent to the rear surface of the object, and the substrate has a laser irradiation hole formed therein through which the laser is irradiated.

19. The reverse-bias processing device of claim 13, wherein the object is a solar cell or a solar module.

20. The reverse-bias processing device of claim 13, wherein the reverse-bias processing device is configured to improve contact resistance between an electrode and a light-receiving surface of a solar cell serving as the object, by utilizing laser and reverse bias.
